(19) United States
(12) Patent Application Publication
(10) Pub. No.: US 2011/0267148 A1
(43) Pub. Date: Nov. 3, 2011

(54) Multiphase VCO Circuits and Methods with Wide Tuning Range

(75) Inventors: Mahdi Bagheri, Carlsbad, CA (US); Rahim Bagheri, Carlsbad, CA (US)

(73) Assignee: WiLinx Corporation, Carlsbad, CA (US)

(21) Appl. No.: 13/095,148

(22) Filed: Apr. 27, 2011

Related U.S. Application Data
(60) Provisional application No. 61/328,998, filed on Apr. 28, 2010.

(51) Int. Cl. H03B 5/12

(52) U.S. Cl. 331/117 FE

(57) ABSTRACT

A Multiphase VCO Circuits and Methods with Wide Tuning Range have been disclosed.

### RELATED APPLICATION

The present application for patent is related to U.S. Patent Application No. 61/326,185 entitled “CMOS Quadrature Oscillator with Deterministic Output Sequence” filed Apr. 28, 2010, pending, by the same inventors and is hereby incorporated herein by reference.

### FIELD OF THE INVENTION

The present invention pertains to VCO circuits and methods. More particularly, the present invention relates to Multiphase VCO Circuits and Methods with Wide Tuning Range.

### BACKGROUND OF THE INVENTION

The present invention related to voltage controlled oscillators (VCO), and in particular to voltage controlled oscillators which have extended locking range by switching among a set of determined modes of oscillation. Furthermore this invention is related to the quadrature VCOs (QVCO) which can generate a determined quadrature output sequence phase.

Oscillator circuits are used in electronic systems to generate a pure oscillatory signal at the desired frequency (f_{osc}). The waveform can ideally be defined as:

Vosc(t)=A*sin(2*pi*f_{osc}*t)

It is important that Vosc(t) has very low phase noise (the noise which adds to the phase component of Vosc(t) in above equation).

The oscillator output signal is used in different ways, such as the clock signal for clocking the digital and analog circuits, or as the local oscillator signal (LO) in communication systems. When used in communication systems (e.g. a Radio), changing the oscillator frequency (f_{osc}) typically controls and changes the channel of communication. Therefore it is desired to be able to tune f_{osc} over a given range to be able to change the communication channels. And thus voltage controlled oscillators (VCO) or digitally controlled oscillators (DCO) are used where f_{osc} is controlled by one or more analog or digital control signals. VCO (or equivalently DCOs) can oscillate within a limited frequency range, which is defined as VCO tuning range.

Tuning range=(f_{osc-max}−f_{osc-min})/(f_{osc-average})

The inevitable variations in manufacturing process parameters, operation temperature and voltage supply of the circuit usually changes the f_{osc}. Therefore VCO tuning range should be wide enough to cover such variations on top of the range required by the system (e.g. the channels to be covered by a radio).

Among various uses of VCOs, typically the requirements of the VCO used for wireless communications systems are the most challenging. Because a low cost, low power and small foot print implementation must meet the most stringent phase noise requirements in such systems. New wireless systems are targeting to offer as many wireless standard and frequency bands as possible. This would require the system to be tunable over a significantly larger range compared to traditional single standard/band wireless systems.

The stringent requirements have made it difficult to design VCOs as part of integrated circuits (IC) with more than 10-20% tuning range. This is not sufficient for multi standard/multi band systems. Thus for the systems where wider tuning range is needed, other alternatives such as including multiple VCOs (each VCO designed for a subset of bands or standards) have been chosen (as shown in FIG. 1). This naturally adds to the system cost, noting that the wireless communication system VCOs usually use large inductors to meet the low phase noise requirements.

The multiple VCO cost impact on the overall system cost is being more pronounced in future for the following reasons. First, the continuous trend in implementing new circuits or porting older designs into lower geometry technology nodes to save in cost, area and power consumption is resulting in higher “cost per area” or $/mm². On the other hand, inductors (a must part in high quality VCOs) are passive components and typically don't shrink in size when technology node scales, in contrary to transistors and logic circuits which benefit significantly from technology scaling. Second, there is a growing trend—as a result of advancement in design techniques and technology scaling—to replace most other analog/RF blocks with a fully digital or digital friendly implementation. Third, most of the system blocks are being designed to be shared for multiple standard/band uses while in a multiple VCO implementation this is not the case.

As a result the cost contribution of multiple-VCO implementation is being high and there is a need to design VCOs with wide tuning range to replace multiple VCO design approaches.

Modern communication systems also typically require the LO signals to be in quadrature phase FIG. 2 shows a typical full transceiver system where quadrature phase LO (LO-I and LO-Q) are both used to feed the I and Q paths of the transmit or receive paths. FIG. 2-B shows the quadrature LO signals (LO-I and LO-Q) both in time and frequency domain (phasor representation).

And therefore there has been various design methods to design low power, small size quadrature LO signal generators. Among those the most common method for quadrature LO generation is a differential oscillator followed by a divide-by-two (FIG. 3), which generates the quadrature signal [1]. This requires the VCO to oscillate at least at twice the highest carrier frequency (channel frequency). Another approach, as shown in FIG. 4, is a differential oscillator followed by one or more poly-phase filters [2] which suffers from tuning range, accuracy, and loss in the filter.

With these limitations in mind, LC Quadrature oscillators (LC-QOSCs) have been extensively investigated [3]-[6]. These VCOs typically consist of two or more VCOs coupled together and generate a quadrature output. LC-QOSCs are either parallel coupled [3], or series coupled [4] as shown in FIG. 5. However one well-known problem with these oscillators is that they might have more than one stable mode, each with a different quadrature sequence (FIG. 6) [5]. This phase ambiguity makes the QOSC ill-suited for some transceiver architectures unless a phase correction technique is used. Ref [7] uses a post processing phase correction technique. In this case, a multiplexer and a polarity detector is connected to the output of the QOSC and, upon detection of the wrong sequence, a multiplexer exchanges the VCO-output to LO signal routings (FIG. 7).

Even though [7] post VCO correction method, guarantees that the LO signals always have proper sequence it has a significant limitation, where the QOSC frequency tuning range can be significantly reduced or even zeroed. To clarify the issue, assume that the two stable modes of the oscillator operation are LOI-leads-LOQ (mode 1, FIG. 6A) or LOI-lags-LOQ (mode 2, FIG. 6B). The analysis in [5] shows that mode 1 operates at a frequency of ω1, which is higher than the single oscillator oscillation frequency, ω1=ωo+Δωc. The same analysis shows that in mode 2 the oscillation frequency is lower than ωo by almost Δωc. Intuitively we can say that in one mode the effect of the coupling is the addition of a positive reactance in parallel with the tank, which lowers the oscillation frequency, ωo, by Δωc (FIG. 8). In the other mode the effect is like adding a negative reactance in parallel with the tank, which increases the frequency of oscillation by Δωc. Now if QVCO chose to randomly oscillate at each mode (or sequence) the guaranteed tuning range (effective tuning range) is the overlap of the tuning range of the two modes.

In practical cases, the guaranteed frequency tuning range is significantly reduced or possibly zeroed (in case of Δωt≦Δωc as shown in FIG. 8). For example, FIG. 9 shows the simulation result for a S-QOSC, which can oscillate in two different quadrature modes—between 2 and 2.5 GHz in one mode and between 1.4 and 1.9 GHz in the other mode, and so the effective tuning range is zero. In other words, such a QOSC cannot be used in a PLL, even with the post-VCO phase correction solution proposed in [7]. This problem can be alleviated only if the QOSC is forced to generate the correct output phase. With this insight, there is a need to design QVCOs with deterministic output sequence.

FIG. 1: Prior Art, Multiple VCO approach for covering wide tuning range.

FIG. 2: Quadrature phase LO signals (LO-I and LO-Q) are typically used in modern transceivers to improve the radio spectral usage efficiency. A—Full transceiver block diagram with I and Q receive and transmit paths. B—Time domain and phasor representation of Quadrature phase LO signals (LO-I and LO-Q).

FIG. 3 Prior art shows a quadrature LO generation method using divide-by-2 following a VCO.

FIG. 4 Prior art shows quadrature LO generation method using poly-phase (phase shifting) filters following the VCO.

FIG. 5, Prior art, A—Parallel coupled LC-QOSC, B-Series Coupled LC-QOSC.

FIG. 6: LC-QOSC has more than one stable mode of oscillation. Modes have different output sequence. A—Clock wise sequence, B-Counter clock-wise sequence.

FIG. 7: Prior art teaches how to correct LC-QOSC phase ambiguity by post-VCO sequence correction using a multiplexer and polarity detector.

FIG. 8: Two different modes of oscillation (different LC-QVCO output sequences represented by Mode-1 and Mode-2) have different frequency of oscillation and therefore the effective tuning range is the overlap of the two tuning ranges in a prior art implementation.

### REFERENCES

[1] J. Maligeorgos and J. Long, “A low-voltage 5.1-5.8-GHz imagereject receiver with wide dynamic range,” IEEE Journal of Solid-State Circuits, vol. 35, no. 12, pp. 1917-1926, December 2000.
[2] J. Crols and M. Steyaert, “A single-chip 900 MHz CMOS receiver front-end with a high performance low-IF topology,” IEEE Journal of Solid-State Circuits, vol. 30, no. 12, pp. 1483-1492, December 1995.
[3] A. Rofougaran, J. Rael, M. Rofougaran, and A. Abidi, “A 900 MHz CMOS LC-oscillator with quadrature outputs,” in IEEE International Solid-State Circuits Conference, Digest of Technical Papers, February 1996, pp. 392-393.
[4] P. Andreani, A. Bonfanti, L. Romano, and C. Samori, “Analysis and design of a 1.8-GHz CMOS LC quadrature VCO,” IEEE Journal of Solid-State Circuits, vol. 37, no. 12, pp. 1737-1747, December 2002.
[5] A. Mirzaei, M. Heidari, R. Bagheri, S. Chehrazi, and A. Abidi, “The quadrature LC oscillator: A complete portrait based on injection locking,” IEEE Journal of Solid-State Circuits, vol. 42, no. 9, pp. 1916-1932, September 2007.
[6] L. Romano, S. Levantino, C. Samori, and A. Lacaita, “Multiphase LC oscillators,” IEEE Transactions on Circuits and Systems I: Regular Papers, vol. 53, no. 7, pp. 1579-1588, July 2006.
[7] C.-W. Yao and A. Willson, “Energy circulation quadrature LCVCO,” in Proceedings IEEE International Symposium on Circuits and Systems, 2006, pp. 4006-4009.

### BRIEF DESCRIPTION OF THE DRAWINGS

The invention is illustrated by way of example and not limitation in the figures of the accompanying drawings in which:

FIGS. 1-9 illustrates prior approaches;

FIGS. 10-19 illustrate various embodiments of the present invention.

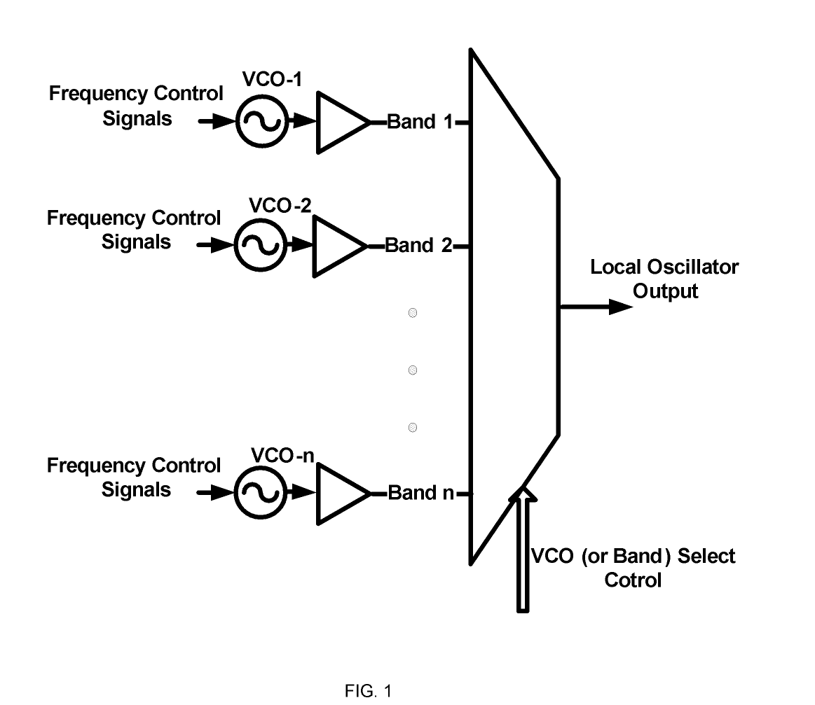

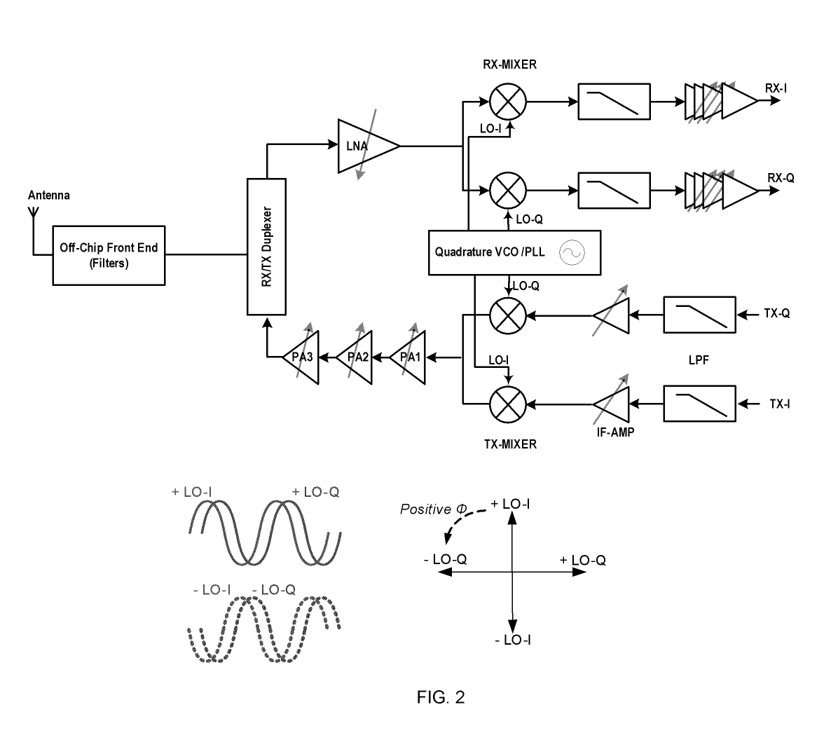

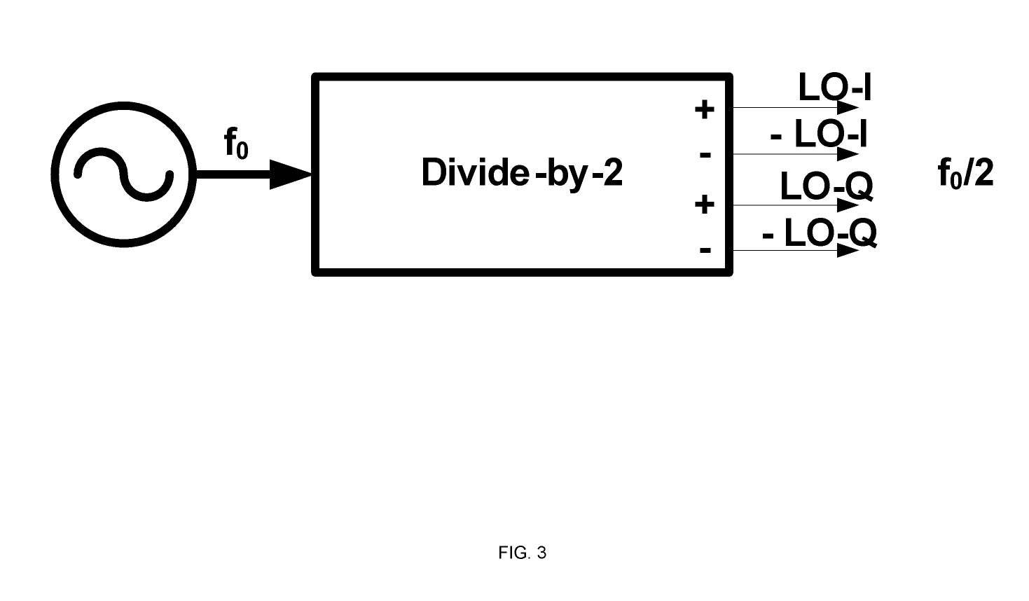

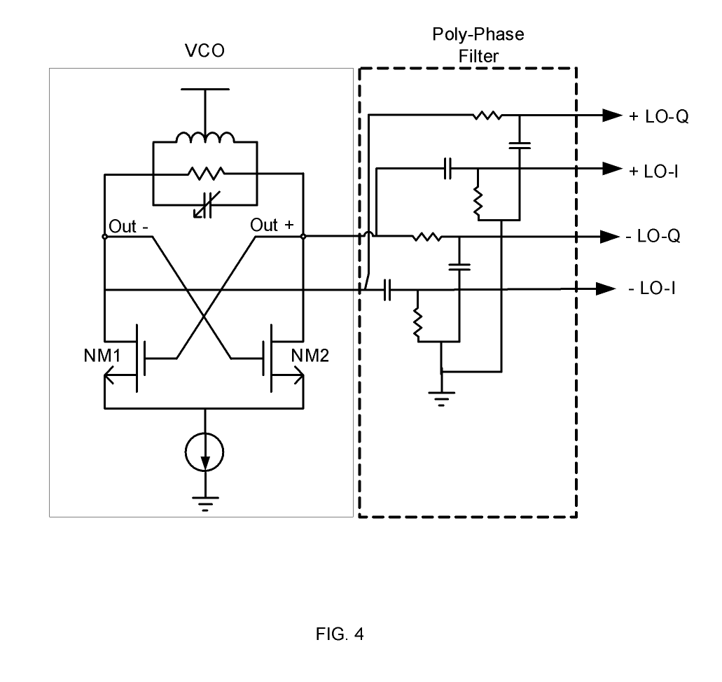

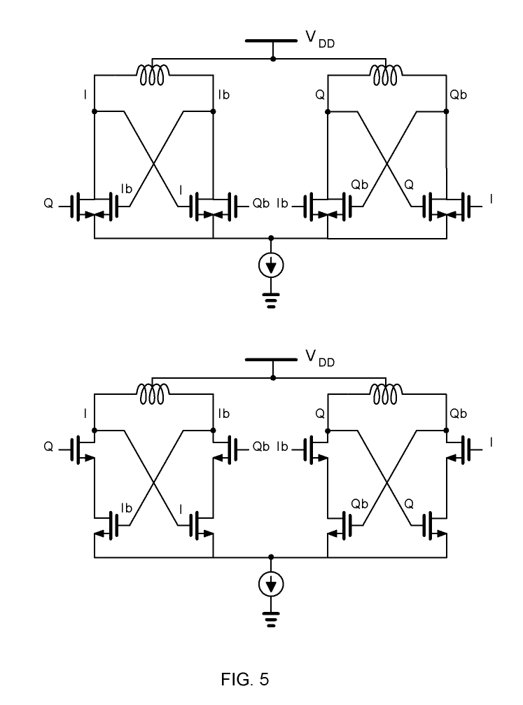

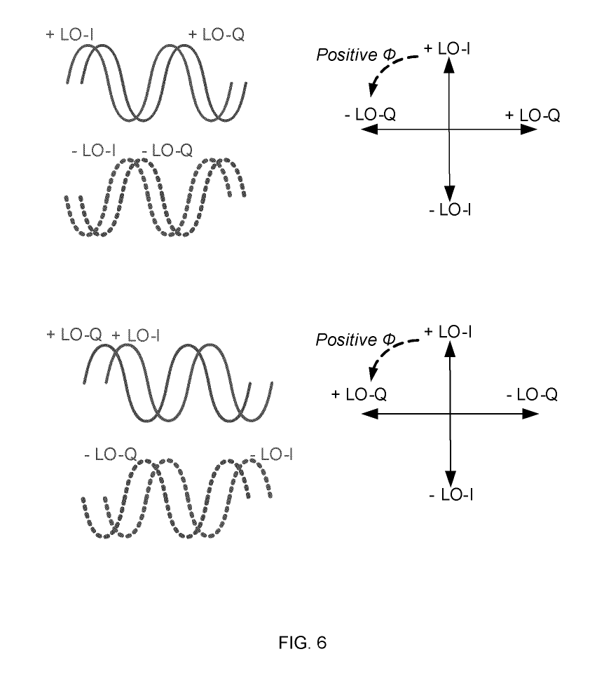

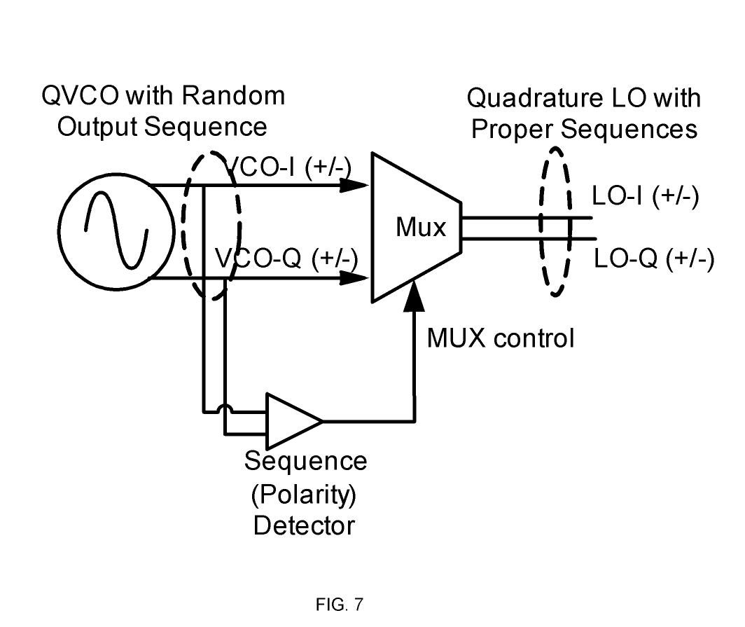

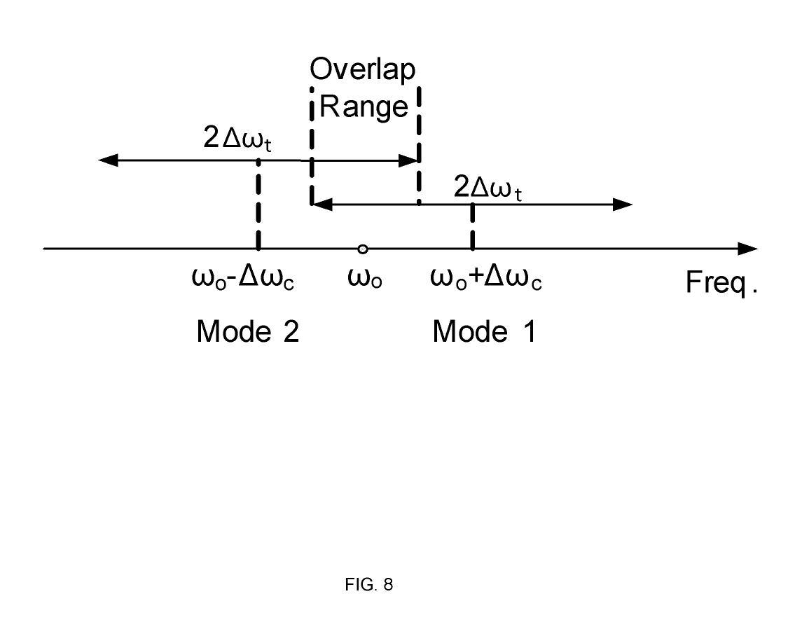

### DETAILED DESCRIPTION

Embodiments of the present invention include circuit and methods that enhance the locking range of the VCOs.

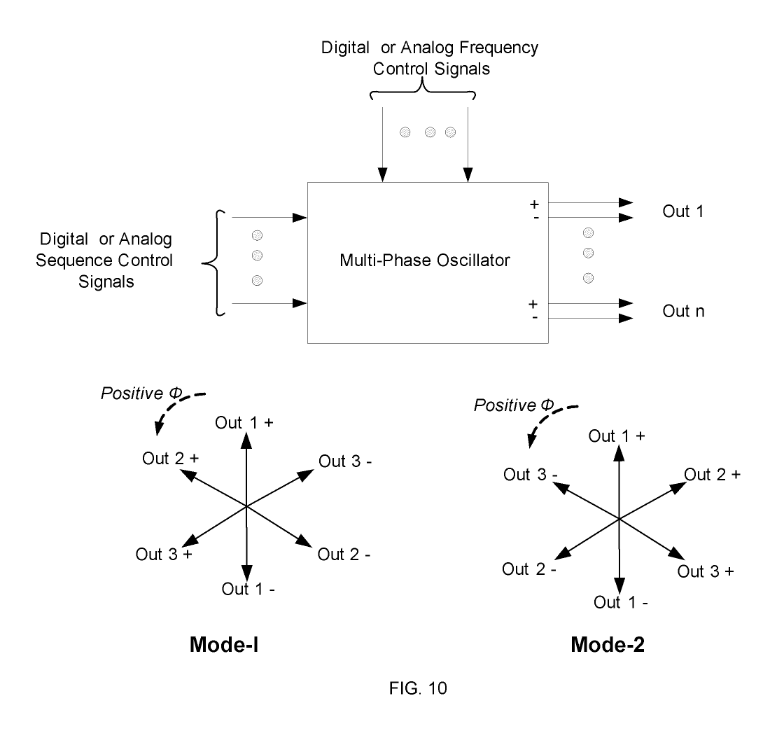

In one embodiment, the present invention includes a multi-phase oscillator tunable over a frequency range and with programmable output phase sequence, a first set of control signals (one or more, digital or analog), a second set of control signals (one or more, digital or analog) for controlling the output phase sequence, wherein the first set of signals control the frequency of oscillation without changing the output phase and the second set of controls change the output phase sequence (FIG. 10).

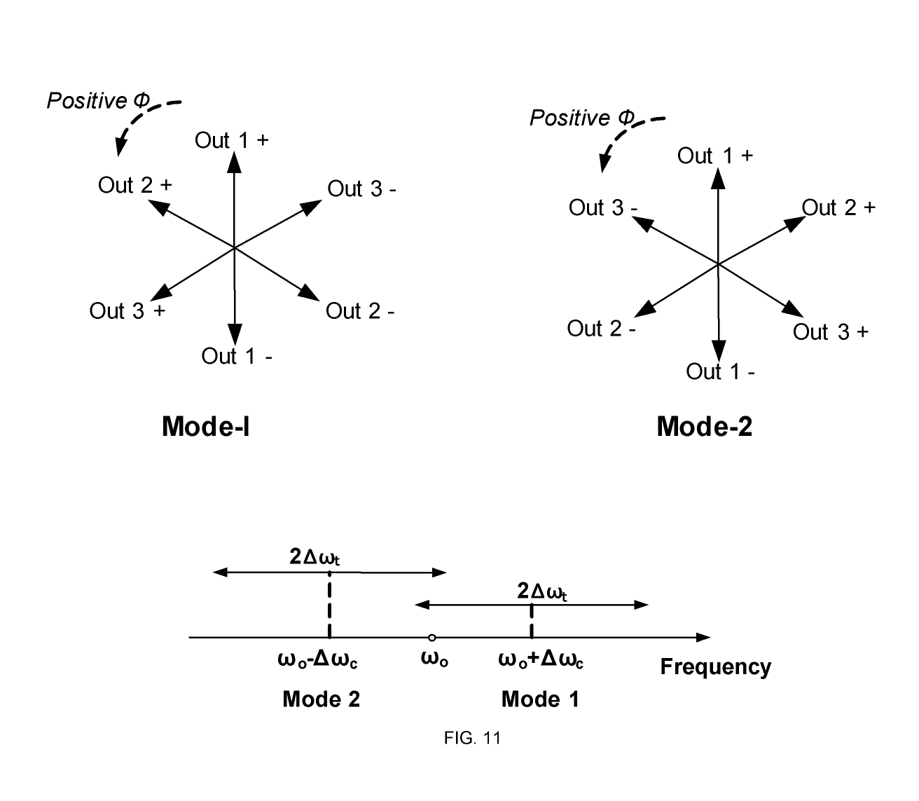

In another embodiment, the present invention includes a multi-phase oscillator tunable over a frequency range, a first set of control signals (one or more, digital or analog), a second set of control signals (one or more, digital or analog) for controlling the output phase sequence, wherein the first set of signals control the frequency of oscillation without changing the output phase and the second set of controls change the frequency of oscillation by changing the output phase sequence (FIG. 11).

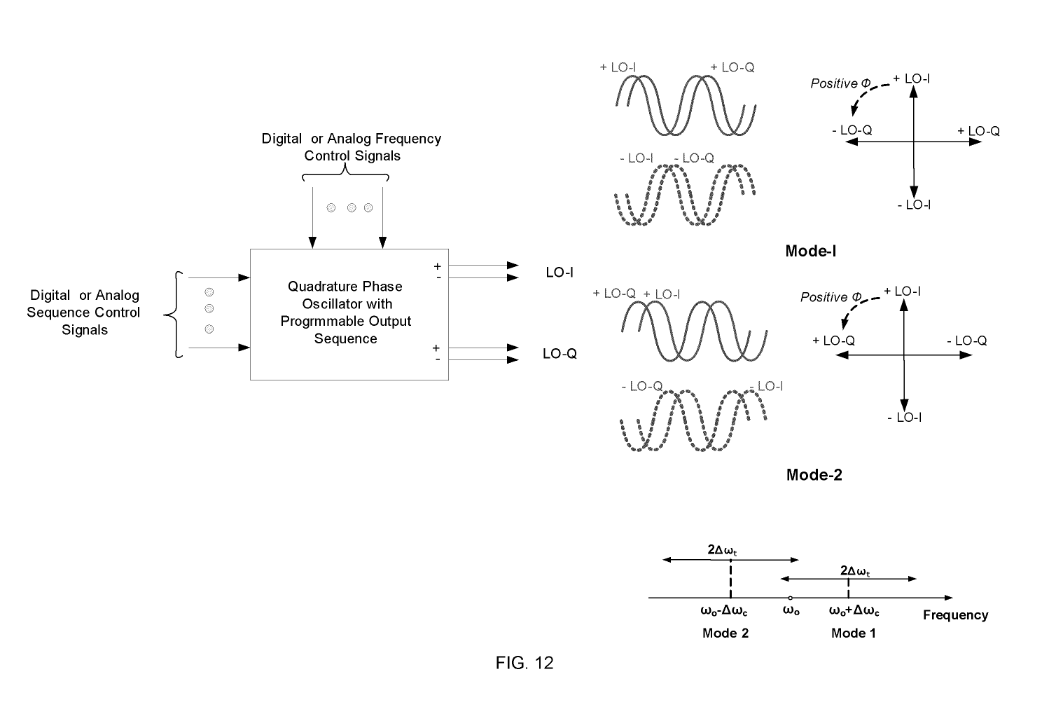

In yet another embodiment, the present invention includes a quadrature phase oscillator, a first set of control signals (one or more, digital or analog), a second set of control signals (one or more, digital or analog) for controlling the output phase sequence, wherein the first set of signals control the frequency of oscillation without changing the output phase and the second set of controls change the frequency of oscillation by changing the quadrature output sequence (in other words by swapping I and Q outputs, FIG. 12.)

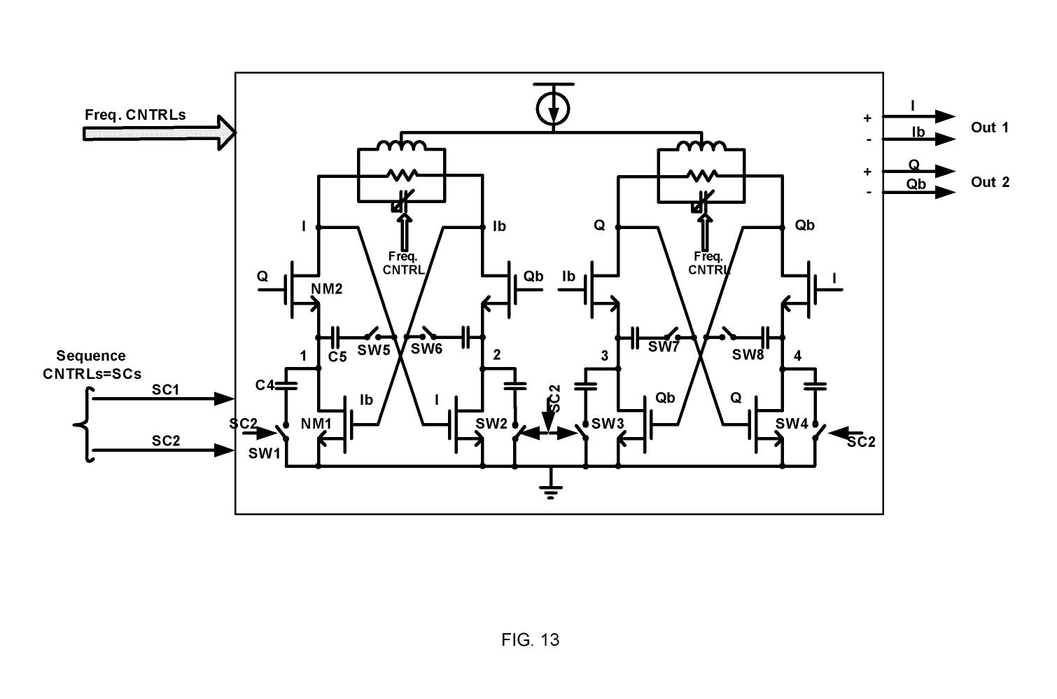

In yet another embodiment the present invention may include an electronic circuit comprising a . . . FIG. 13 . . . wherein sequence control signals (SC1, SC2) are coupled to switches (Sw1-Sw8) and change the output sequence and frequency.

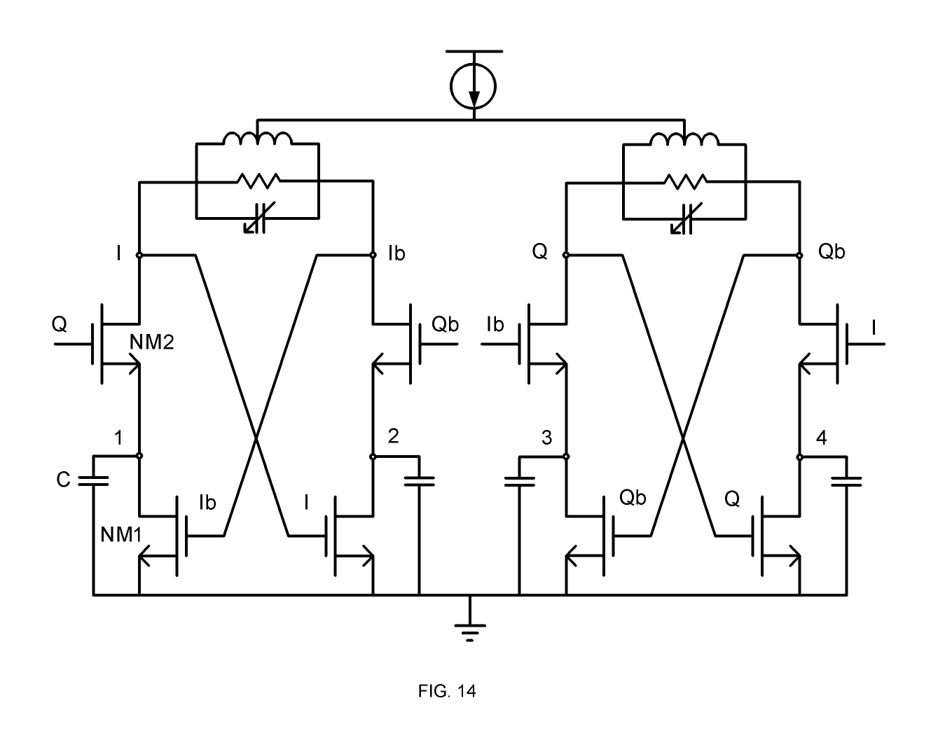

In yet another embodiment the present invention may include . . . FIG. 14 . . . wherein the capacitors C1-C4 are added to prior art quadrature VCOs to force oscillator output sequence to one of the multiple possibilities.

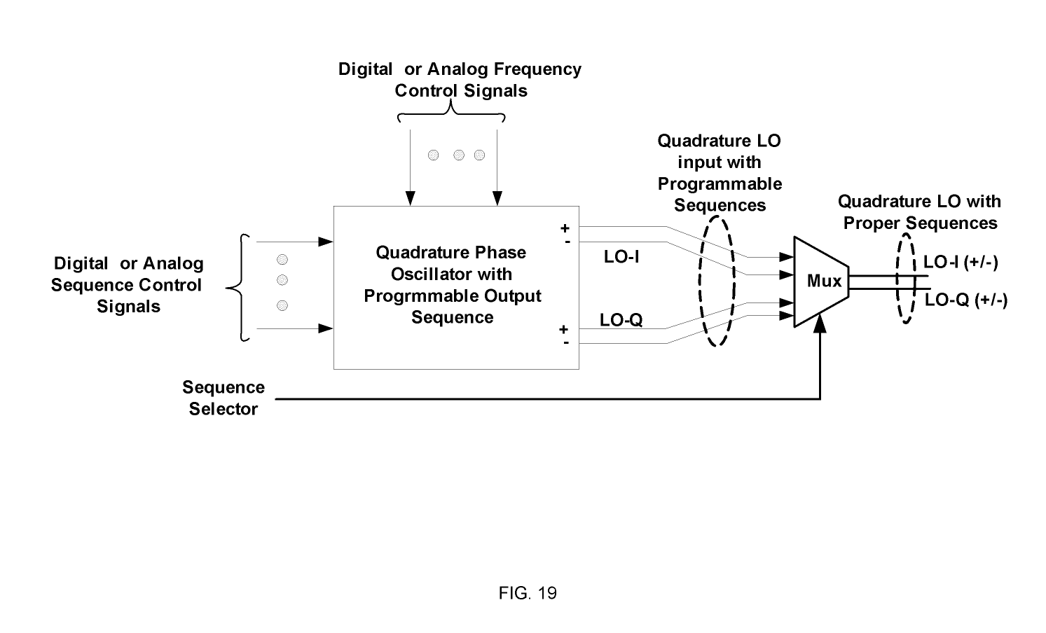

In yet another embodiment of the current invention a post-VCO sequence correction MUX is added to the output of the “programmable sequence multiphase-VCO” to correct for the output sequence of the VCO if needed when its output sequence is switched to change the oscillation frequency. (FIG. 19)

In one embodiment, the present invention includes an integrated circuit comprising means for generating multi phase local oscillator signals, means for providing oscillation frequency tuning, means for changing the sequence of the local oscillator signals, and in accordance therewith, providing a local oscillator signal with wide frequency tuning range.

Described herein are techniques for enhancing the frequency tuning range of oscillators. In the description, for purposes of explanation, numerous examples and specific details are set forth in order to provide a thorough understanding of different aspects of the present invention. It will be evident, however, to one skilled in the art that the present invention as defined by the claims may include some or all of the features in these examples alone or in combination with other features described below, and may further include obvious modifications and equivalents of the features and concepts described herein.

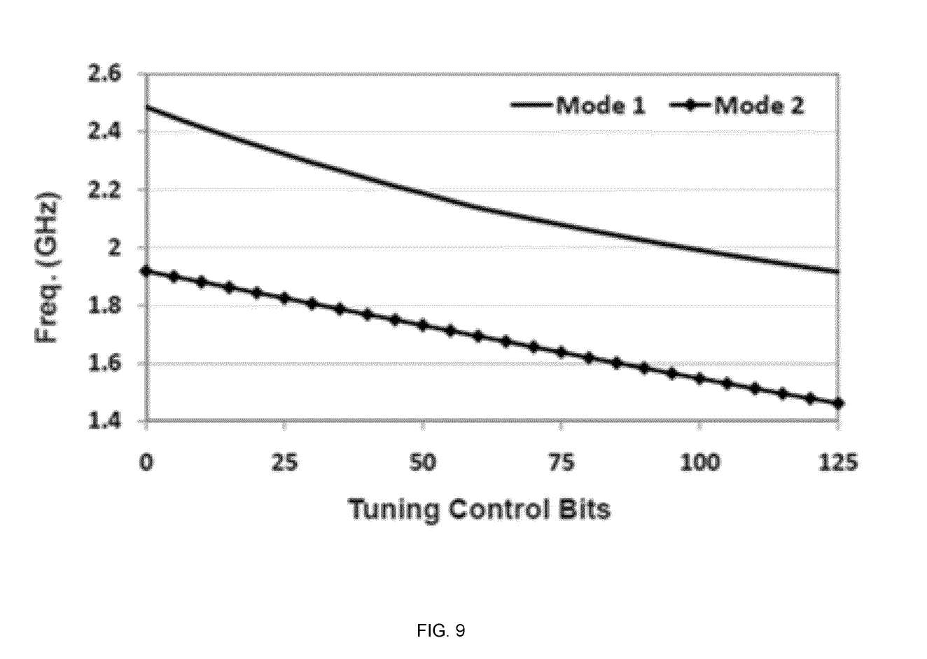

FIG. 9 An example simulation result of a QVCO where its effective tuning range is almost zero due to sequence ambiguity issue.

FIG. 10 Proposed Multi-phase VCO, as one embodiment of present invention, where a set of control signals (digital or analog) controls the sequence (modes) of oscillation.

FIG. 11: Another embodiment of current invention showing proposed Multi-phase VCO of FIG. 10, where design parameters are chosen such that oscillation frequencies of Mode-I and Mode-II are set at two different ranges. Sequence control signals are used to change the mode of oscillation thereby frequency of the oscillation.

FIG. 12: A—QVCO with programmable sequence (as another embodiment of current invention) is shown. B—Frequency tuning range is extended by switching the mode of oscillation (output sequence).

FIG. 13: A sample implementation of a QVCO where output sequence is programmable, another embodiment of present invention.

FIG. 14 A sample QVCO circuit where QVCO output sequence has no phase ambiguity by addition of the capacitor C, another embodiment of present invention.

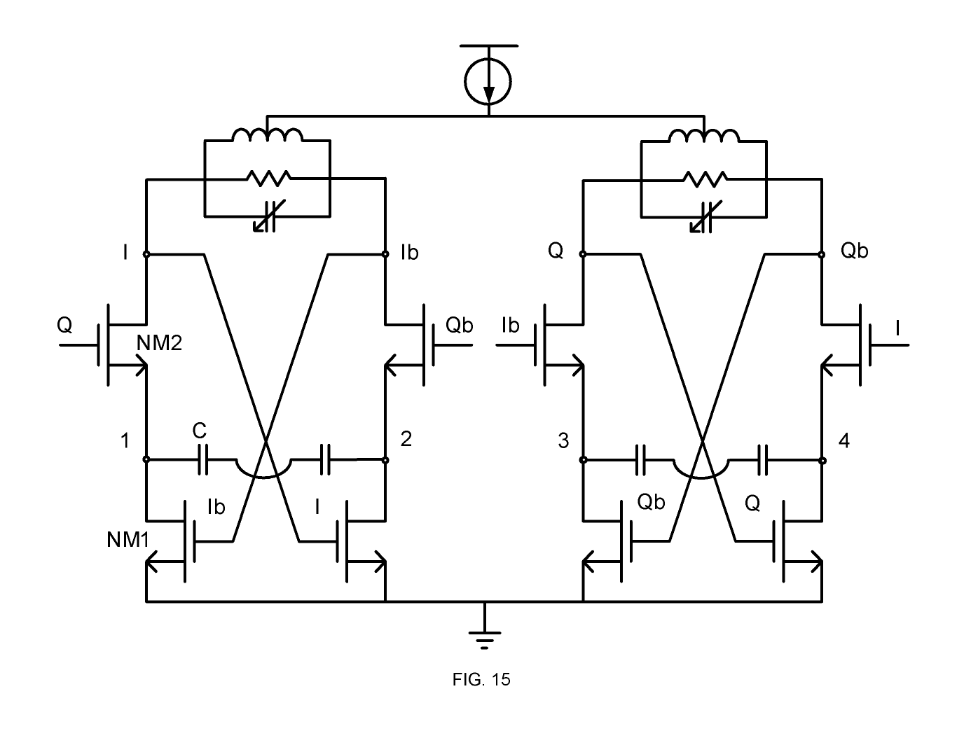

FIG. 15 A sample QVCO circuit where QVCO output sequence has no phase ambiguity by addition of the capacitor C in differential form, another embodiment of present invention.

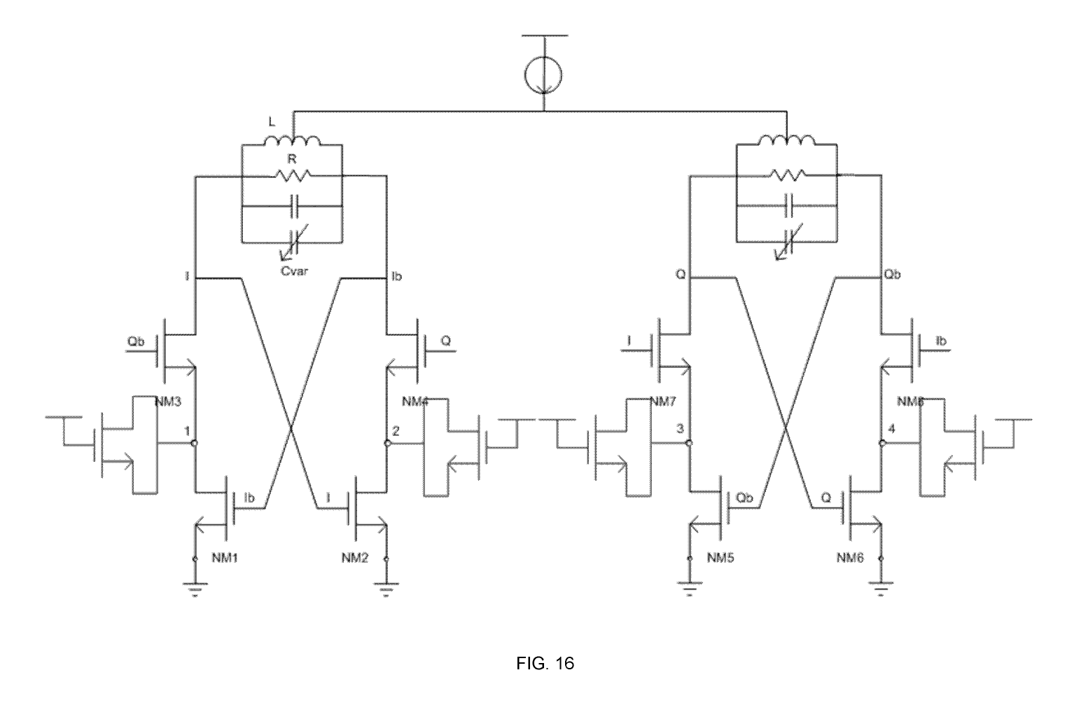

FIG. 16 A sample QVCO circuit where QVCO output sequence has no phase ambiguity by addition of the Mosfet-Capacitor C, another embodiment of present invention.

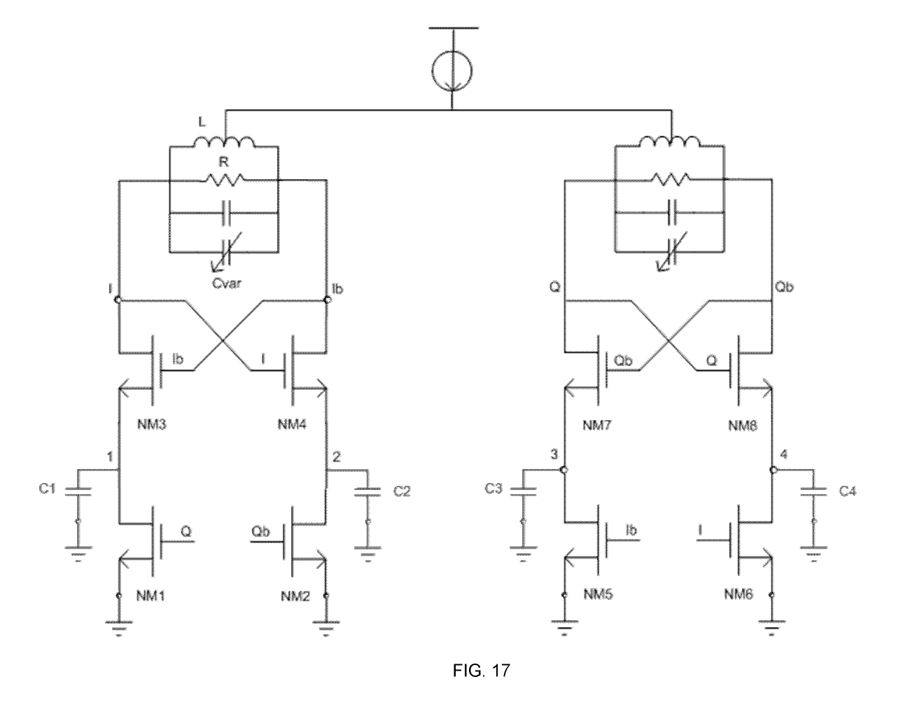

FIG. 17: Another sample QVCO circuit where QVCO output sequence has no phase ambiguity by addition of the Capacitor C, another embodiment of present invention. This time I/Q cross coupled transistors (NM1, NM2, NM5, NM6) are at the bottom.

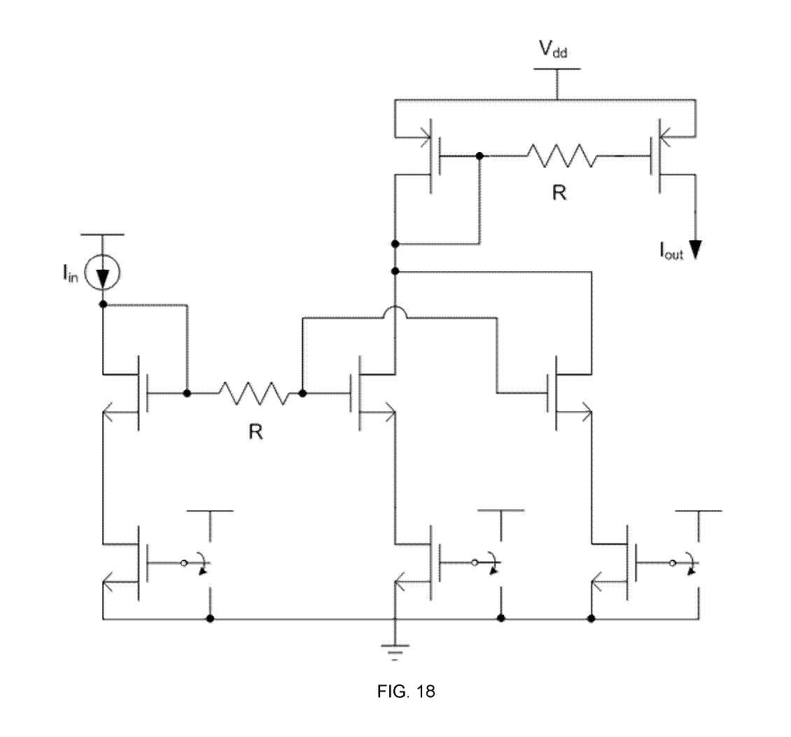

FIG. 18: Noise filtering circuit for bias path is demonstrated. In a wide tuning range QVCO, bias current noise can contribute in overall phase noise and thus supply noise filtering is critical.

FIG. 19: Another embodiment of current invention shows that when output sequence is switched to change the frequency of oscillation, then a post VCO phase correction is added to provide proper LO phases to the Transmitter or Receiver path.

Thus a Multiphase VCO Circuits and Methods with Wide Tuning Range have been described.

What is claimed is:

1. An apparatus for a multiphase VCO circuit with enhanced locking range.

2. A method for a multiphase VCO circuit with enhanced locking range.

3. A circuit for a quadrature VCO with enhanced locking range.
